(19) United States
(12) Patent Application Publication
(10) Pub. No.: US 2011/0105334 A1
(43) Pub. Date: May 5, 2011

(54) APPARATUS AND METHOD FOR INSTALLING COOLING TUBES ON A COOLED FORMER

(76) Inventor: Neil John Belton, Didcot Oxfordshire (GB)

(21) Appl. No.: 11/913,792

(22) PCT Filed: Mar. 2, 2006
(86) PCT No.: PCT/EP2006/001898

§ 371 Date: Nov. 7, 2007

(30) Foreign Application Priority Data
May 18, 2005 (GB) 0510125.8

(51) Int. Cl. G01R 33/035; H01L 39/02; H01F 6/04; B23P 15/26

(52) U.S. Cl. 505/162; 505/163; 29/890.045; 335/216

(57) ABSTRACT

A superconducting magnet structure has a thermally conductive former with a former body having a former surface and a channel in said former surface that is open at said former surface, a thermally conductive tube disposed in the channel and configured to receive a circulating coolant therethrough, and the former body has at least one deformable retaining element integrally formed as a part of said former body and projecting from said surface of the former body next to the channel and being deformed over said tube in the channel to cover the tube in said channel and retain the tube in the channel.

### BACKGROUND OF THE INVENTION

1. Field of the Invention

The present invention relates to cryogenic cooling equipment, and particularly relates to cryogenic cooling equipment for cooling magnet coils to superconducting temperatures.

2. Description of the Prior Art

FIG. 1 shows a typical arrangement of superconducting magnet coils 12 wound onto a former 10. The former may be of any structural material, but is preferably of a composite such as fiberglass reinforced resin, or a thermally conductive material such as aluminum. Stainless steel is also commonly used for the coil former.

The magnet comprising former 10 and coils 12 is held within a cryogen tank 14. The cryogen tank 14 is at least partially filled with a liquid cryogen, such as liquid helium. The liquid cryogen boils, holding the magnet at a steady temperature, being the boiling point of the cryogen. For helium, this is approximately 4K. In normal operation, boiled off cryogen is recondensed back into liquid by a recondensing refrigerator located within the service neck 20.

An outer vacuum chamber 16, surrounds the cryogen vessel. The space between the cryogen vessel 14 and the outer vacuum chamber 16 is evacuated, to provide thermal insulation. Thermal shields 18 may be placed in the space between the cryogen vessel and the outer vacuum chamber, to reduce heat influx to the cryogen vessel by thermal radiation from the outer vacuum chamber.

The cryogen tank holds a relatively large volume of cryogen. The provision and maintenance of such a large volume of cryogen is costly. The required volume of the cryogen tank also determines, to a significant degree, the final size of the cryostat containing the magnet.

An object of the present invention is to provide an apparatus and methods for cooling superconducting magnets while reducing or avoiding the need for immersion of the magnet in a tank of liquid cryogen.

The above object is achieved in accordance with the present invention by a superconducting magnet structure having a number of superconducting coils mounted on a thermally conductive former, the former being cooled by a cooling arrangement that includes a thermally conducting tube at least substantially contained within a channel in the body of the former, the thermally conductive tube being in thermal and mechanical contact with the body of the former and being configured to receive a circulating coolant therethrough, and wherein the former body has at least one deformable retention element integrally formed in the body at a side of the channel on opposite sides of the channel, the retention element being deformed over the thermally conductive tube in the channel to retain the thermally conductive tube in the channel.

The retention element can be a retention strip or a retention lug.

The above object is also achieved in accordance with the present invention by a method for manufacturing a superconducting magnet structure that includes the steps of forming a channel in a former body of a thermally conductive former and integrally, forming at least one deformable retaining element at a side of the channel, placing a thermally conductive tube in the channel, and thereafter deforming the retaining element onto the tube in the channel, to retain the tube in the channel in mechanical contact with the channel surface.

### BRIEF DESCRIPTION OF THE DRAWINGS

FIG. 1 shows a typical arrangement of a superconducting magnet within a cryostat.

FIG. 2 shows a superconducting magnet within a cryostat, modified according to the present invention.

FIG. 3 schematically illustrates an arrangement for causing the liquid cryogen to circulate around the cryogen tubes.

FIG. 4 shows a cryogen tube housed within a channel, according to a feature of the present invention.

FIG. 5 shows a cryogen tube housed within a channel, according to a feature of another embodiment of the present invention.

FIG. 6 illustrates a process of retaining a cryogen tube within a channel, according to a feature of an embodiment of the present invention.

FIG. 7 illustrates a cryogen tube retained within a channel as a result of the process illustrated in FIG. 6.

FIG. 8 shows a tool, according to an aspect of the present invention, useful for performing the process illustrated in FIG. 6.

### DESCRIPTION OF THE PREFERRED EMBODIMENTS

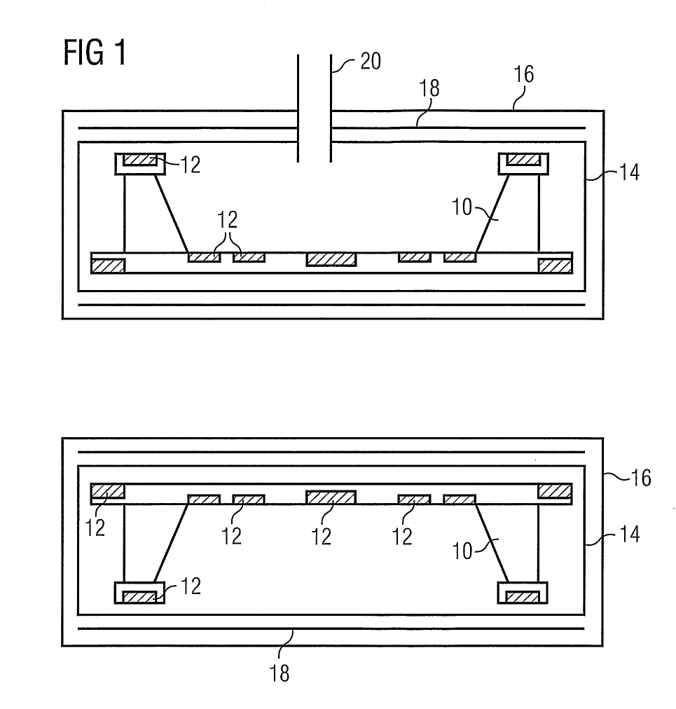

According to the present invention, the cryogen tank 14 of FIG. 1 is dispensed with. A tube of thermally conductive material is provided, in thermal contact with the former 10, which is also of thermally conductive material.

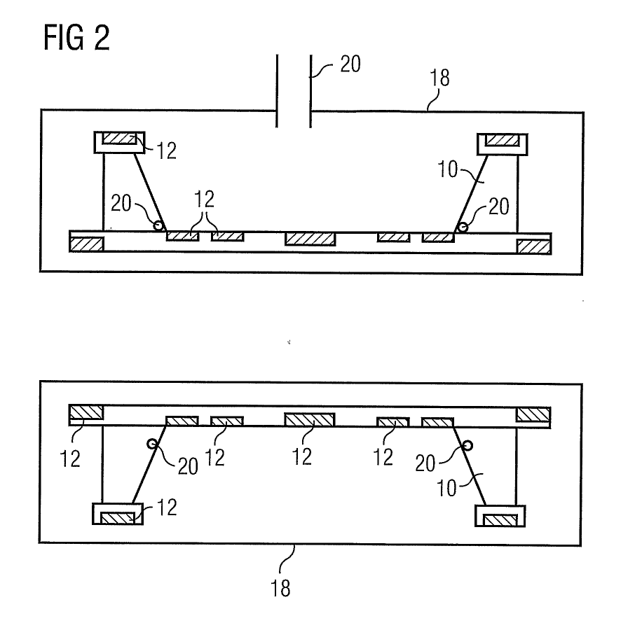

Preferably, as shown in FIG. 2, a cryogen tube 20 is provided, following a circumference near each end of the former. In use, liquid cryogen circulates around the cryogen tubes. A refrigerator is provided, to supply cryogen at about its boiling point. For example, the cryogen may be liquid helium at a temperature of about 4K. The liquid cryogen circulates through the cryogen tubes 20 and absorbs heat from the former. The heat is carried to the refrigerator, where the heat is removed. The cooled former 10, in turn, cools the coils 12, holding them in a superconducting state, below their critical temperature.

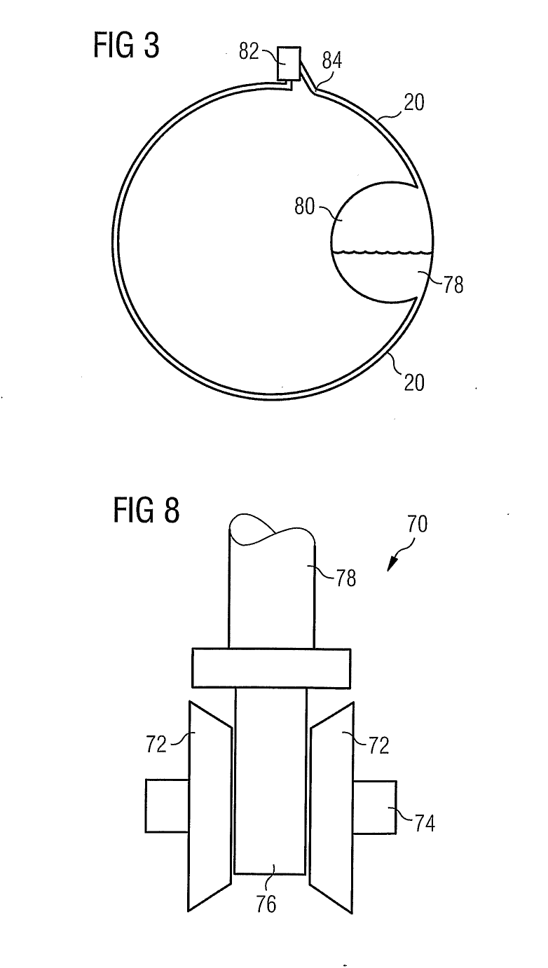

FIG. 3 schematically illustrates an arrangement for causing the liquid cryogen 78 to circulate around the cryogen tubes 20. A relatively small cryogen tank 80 is provided in the cryogen tube circuit. A recondensing refrigerator 82 is also provided. In operation, some of the liquid cryogen 78 in cryogen tube 20 will absorb heat from the cryogen tube 20, and thus from the former 10. This will cause some of the liquid cryogen 78 to boil into a gaseous state. The boiled-off cryogen gas 84 will rise toward the top of the cryogen tube circuit, and will enter the recondensing refrigerator 82. The recondensing refrigerator 82 operates to cool the cryogen gas 84, recondensing it into liquid cryogen 78, and removing heat from the system. As illustrated in FIG. 3, boiling of the liquid cryogen will take place substantially on the right-hand side of the circuit as illustrated, and will rise to the recondensing refrigerator 82. The recondensed liquid cryogen supplied by refrigerator 82 will descend through the left hand side of tube 20, as illustrated. Hence, this arrangement provides continuous circulation of the cryogen, and effective cooling. Although a cryogen tank 80 is required, the volume of liquid cryogen 78 required is very much reduced as compared to cryogen tanks 14 of the prior art, which allowed immersion of the magnet in a bath of liquid cryogen.

In a preferred embodiment, the tube 20 is a stainless steel tube, held in position by mechanical deformation of lugs or retaining strips formed in the material of the former. In certain embodiments, channels are formed in the material of the former to house the tube. The tube may be of other materials of high thermal conductivity, such as copper.

In the case of an aluminum former, it has been found that the thermal expansion of a stainless steel tube is sufficiently similar to the thermal expansion of the former. The material chosen for the tube must be sufficiently mechanically strong to withstand the pressure of the cryogen.

If the cryogen tube 20 is to be retained by mechanical deformation, then this process may be performed after the magnet coils are wound onto the former, if preferred.

A particularly preferred embodiment is illustrated in FIG. 4. According to this embodiment, a channel 30 is machined in the material of the former 10 to house the tube 20. The channel 30 may be formed with a profile which is complementary to the cross-section of the tube 20. Two lugs or retaining strips 32 are also machined into the surface of the retainer 10. As illustrated in FIG. 4, this may be achieved by machining three adjacent channels 34, 30, 38 into the material of the former, with the lugs or retaining strips 32 being formed by the material of the former left between the channels.

In an alternative embodiment, illustrated in FIG. 5, a single channel 30 is formed to house the tube, and retaining strips or lugs 32 are formed projecting from the surface of the former.

Preferably, the channel 30 formed for housing the tube 20 is an interference fit, such that the tube may be pressed into position by machine or by hand, and will be retained in position by frictional interaction with the walls of the channel.

As illustrated in FIG. 6, the tube is retained in position by deforming the lugs or retaining strips 32 towards each other, over the tube in the directions of two of the arrows shown. The material of the former should be chosen so that it is malleable yet rigid at room temperature. Certain grades of aluminum and stainless steel have appropriate properties. In this way, the tube 20 is retained in stable position and in good thermal and mechanical contact with the former 10, while requiring no welding or braising step. Since the process uses only machining techniques, the tubes 20 may be installed during the manufacture of the former, resulting in a low cost process.

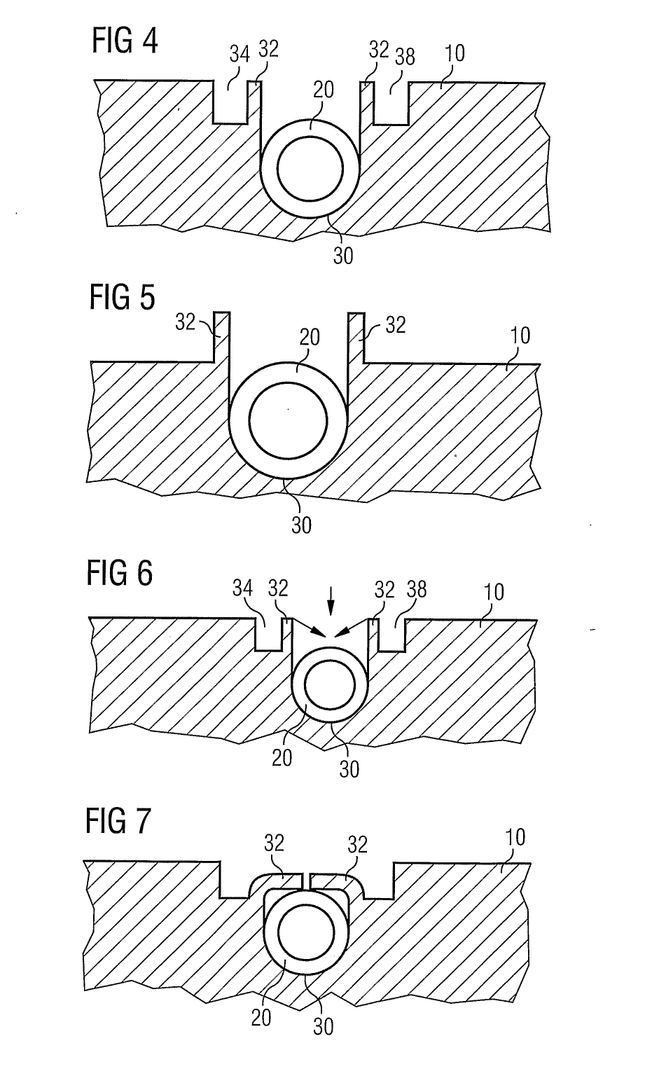

FIG. 7 illustrates the structure after the lugs or retaining strips 32 have been deformed over the tube 30. The tube 30 is protected from damage, for example during handling, by being embedded within the material of the former. It is held in intimate thermal and mechanical contact with the former 10.

FIG. 8 illustrates a tool 70 which may be used to deform the lugs or retaining strips 32 over the tube 30 and so retain the tube in position. The tool 70 comprises a pair of angled forming wheels 72, mounted axially 74 on a spindle 76. The spindle is retained on a tool body 78 which may itself be mounted to a handle for manual use, or may be mounted on a machine for automated or power assisted use. In use, the angled forming wheels 72 are brought to bear on the lugs or retaining strips 32 which run alongside the channel 30 holding the tube 20. Pressure is imparted onto the tool in a direction substantially perpendicular to the surface of the former 10, generally in the direction of the upper arrow shown in FIG. 5. The surfaces of the angled forming wheels 72 are so angled that the pressure they impart on the lugs or retaining strips causes the lugs or retaining strips 32 to be deformed to turn inwards towards each other over the tube 20, as shown in FIG. 7.

The cooling tubes and retaining means according to the present invention provides a cost effective means for cooling equipment such as magnet formers, and so cooling the magnet coils themselves. Such magnet coils and formers may be employed in Nuclear Magnetic Resonance or Magnetic Resonance Imaging. By arranging the cooling of the magnet according to the present invention, the volume of liquid cryogen required may be significantly reduced. For example, a magnet for an MRI imaging system may be cooled according to the present invention with as little as 80-100 liters of cryogen provided to circulate in the tubes 20 according to the arrangement described with reference to FIG. 3. This compares very favorably with present systems which typically require a volume of 2000 liters of cryogen in cryogen tank 14.

For the apparatus cooled according to the present invention, there is no requirement for a cryogen tank 14 enveloping the former 10 and coils 12, so the outer vacuum container may be reduced in size, resulting in a smaller overall system.

Although the present invention has been described with reference to a limited number of specific embodiments, those skilled in the art will recognize that numerous modifications and variations may be made to the present invention, within the scope of the appended claims.

For example, while the present invention may usefully be applied to cooling a superconducting magnet for use in an MRI system, the present invention may be applied to any apparatus which requires cooling.

While a certain particular tool has been described for deforming the lugs or retaining strips, other tools may of course be used to perform this task.

While the invention, has been particularly described in relation to retention of the tube by two lugs or retaining strips 32, the present invention may be embodied by arrangements having lugs or retaining strip along only one side of channel 30.

I claim as my invention:

1-8. (canceled)

9. A superconducting magnet structure comprising:
a thermally conductive former comprising a former body having a former surface and a channel in said former surface that is open at said former surface;
a thermally conductive tube disposed in said channel and configured to receive a circulating coolant therethrough; and
said former body having at least one deformable retaining element integrally formed as a part of said former body, said at least one retaining element projecting from said surface of said former body next to said channel and being deformed over said tube in said channel to cover said tube in said channel and retain said tube in said channel.

10. A structure as claimed in claim 9 wherein said tube has a cross-section, and wherein said channel has a channel profile that is complementary to the cross-section of said tube.

11. A structure as claimed in claim 9 comprising a recondensing refrigerator in communication with said tube that circulates said coolant through said tube.

12. A structure as claimed in claim 9 wherein said coolant is liquid helium.

13. A magnetic resonance imaging system comprising:
a magnetic resonance scanner configured to interact with an examination subject to acquire magnetic resonance data from the subject; and
a superconducting magnet structure in said scanner comprising a thermally conductive former comprising a former body having a former surface and a channel in said former surface that is open at said former surface, a thermally conductive tube disposed in said channel and configured to receive a circulating coolant therethrough, and said former body having at least one deformable retaining element integrally formed as a part of said former body, said at least one retaining element projecting from said surface of said former body next to said channel and being deformed over said tube in said channel to cover said tube in said channel and retain said tube in said channel.

14. A method for manufacturing a cooling arrangement, comprising the steps of:
forming a channel in a thermally conductive body having a body surface, with the channel being open at said surface;
forming at least one deformable retaining element integrally with said body projecting from said body surface at a side of the channel;
placing a thermally conductive tube in the channel; and
deforming said at least one retaining element over the tube in the channel to hold said tube in the channel in mechanical contact with a surface of the channel.

15. A method as claimed in claim 14 comprising forming said at least one retaining element as a retaining strip.

16. A method as claimed in claim 14 comprising forming said at least one retaining element as a retaining lug.
